(19) United States
(12) Patent Application Publication
(10) Pub. No.: US 2020/0083025 A1
(43) Pub. Date: Mar. 12, 2020

(54) ELECTRODE ASSEMBLY AND ETCHING APPARATUS

(71) Applicant: HKC CORPORATION LIMITED, Shenzhen, Guangdong (CN)

(72) Inventor: Huailiang He, Shenzhen, Guangdong (CN)

(21) Appl. No.: 16/312,264

(22) PCT Filed: Sep. 7, 2018
(86) PCT No.: PCT/CN2018/104459

§ 371 Date: Dec. 20, 2018

(51) Int. Cl. H01J 37/32

(52) U.S. Cl. CPC H01J 37/32541; H01J 37/32449

(57) ABSTRACT

An electrode assembly and an etching apparatus are provided. The etching apparatus includes a chamber, a first electrode plate and a second electrode plate. The first electrode plate is arranged in the chamber and having a first central region and a first edge region. First gas inlet holes extend through the first central region, second gas inlet holes extend through the first edge region, and a cross sectional area of the first gas inlet hole is smaller than a cross sectional area of the second gas inlet hole. The second electrode plate is arranged in the chamber and includes a placement region and a second edge region, a substrate to be processed being disposed on the placement region. The chamber is further provided with a gas outlet arranged in the chamber, and the position of the gas outlet is lower than the position of the second electrode plate.

### CROSS-REFERENCES TO RELATED APPLICATION

This application is the International Application No. PCT/CN2018/104459 for entry into US national phase with an international filing date of Sep. 7, 2018 designating US, now pending, and claims priority to Chinese Patent Application No. 201810157608.3, filed on Feb. 24, 2018, the contents of which is incorporated herein by reference in its entirety.

### BACKGROUND

### Technical Field

The present disclosure relates to etching technology, and more particularly to an electrode assembly and an etching apparatus.

### Related Art

With the development of science and technology, electronic devices (such as smart phones, notebook computers, digital cameras, etc.) have become more and more popular, which has greatly increased the demand for liquid crystal displays, which are important components of electronic devices, thereby promoting rapid development of the liquid crystal display panel industry.

An important step in the manufacturing process of the liquid crystal display panel is etching process. Currently dry etching process is the most commonly used etching method in which process gas is used to etch. In the process of manufacturing array substrates by the dry etching process, the process gas is blown to the surface of the substrate to be processed by factors such as the blowing force of the gas intake system, the suction force of the gas suction system and the voltage between the electrode plates, and so on. In the etching process, the process uniformity is usually used to describe the etching degree of the whole workpiece under a certain process. The closer the etching degrees of different positions of the processed surface of the same workpiece are, the higher the process uniformity will be. In order to ensure that various portions of the substrate surface to be processed can be etched simultaneously and to ensure the processing yield and the quality of the workpieces, it is necessary to control the etching degrees of various portions of the substrate to be processed so as to try to ensure that various portions of the substrate surface to be processed are etched at the same rate.

However, in the prior art, due to factors such as the internal design structure of the chamber and the design of the exhaust system, the process gas flows to the corners inside the chamber in the actual operation, and the etching degrees of the four corners are different from that of the other positions, so that the etching degrees of various portions of the substrate to be processed are different, resulting in poor process uniformity of various portions of the substrate to be processed, which results in production scrap.

It is desirable to make improvements in view of the above shortcomings.

### SUMMARY

An embodiment of the present disclosure aims to provide an electrode assembly to solve the existing technical problem that the process uniformity of various portions of the substrate to be processed is poor.

To solve the above technical problem, the present disclosure provides an electrode assembly including:

a first electrode plate having a first central region and a first edge region surrounding the first central region;

first gas inlet holes configured to be connected to a gas intake device, the first gas inlet holes extending through the first central region; and

second gas inlet holes configured to be connected to the gas intake device, the second gas inlet holes extending through the first edge region and surrounding the first gas inlet holes, a cross sectional area of the first gas inlet hole being smaller than a cross sectional area of the second gas inlet hole.

In an embodiment, the first gas inlet holes extend through and arrange in the first central region in a uniform or partially uniform manner.

In an embodiment, the first gas inlet holes extend through and arrange in the first central region in a non-uniform manner.

In an embodiment, the second gas inlet holes extend through and arrange in the first edge region in a uniform or partially uniform manner.

In an embodiment, the second gas inlet holes extend through and arrange in the first edge region in a non-uniform manner.

In an embodiment, the shapes and the sizes of the first gas inlet holes respectively are the same, partially the same or different.

In an embodiment, the shapes and the sizes of the second gas inlet holes respectively are the same, partially the same or different.

In the electrode assembly according to an embodiment of the present disclosure, since the cross sectional area of the first gas inlet hole opened in the first central region is smaller than the cross sectional area of the second gas inlet hole opened in the first edge region, when the process gas enters an etching apparatus through the first gas inlet holes and the second gas inlet holes, the flow rate of the process gas passing through the second gas inlet holes is smaller than the flow rate of the process gas passing through the first gas inlet holes, thereby further reducing the etching rate of the portion of the substrate to be processed corresponding to the first edge region such that the etching rate of the portion of the substrate to be processed corresponding to the first central region is closer to the etching rate of the portion of the substrate to be processed corresponding to the first edge region, thereby effectively improving process uniformity of various portions of the substrate to be processed.

The present disclosure further provides an etching apparatus including:

a chamber;

a first electrode plate arranged at an upper part in the chamber and having a first central region and a first edge region surrounding the first central region;

a second electrode plate arranged at a lower part in the chamber and opposite to the first electrode plate and having a placement region and a second edge region surrounding the placement region, wherein a substrate to be processed is disposed at the placement region;

first gas inlet holes configured to be connected to a gas intake device, the first gas inlet holes extending through the first central region and directly facing the substrate to be processed;

second gas inlet holes configured to be connected to the gas intake device, the second gas inlet holes extending through the first edge region and surrounding the first gas inlet holes, and a cross sectional area of the first gas inlet hole being smaller than the cross sectional area of the second gas inlet hole; and

a gas outlet configured to be connected to a gas suction device, the gas outlet being arranged at the lower part in the chamber and the position of the gas outlet being lower than the position of the second electrode plate.

In an embodiment, the first gas inlet holes extend through and arrange in the first central region in a uniform or partially uniform manner.

In an embodiment, the first gas inlet holes extend through and arrange in the first central region in a non-uniform manner.

In an embodiment, the second gas inlet holes extend through and arrange in the first edge region in a uniform or partially uniform manner.

In an embodiment, the second gas inlet holes extend through and arrange in the first edge region in a non-uniform manner.

In an embodiment, the shapes and the sizes of the first gas inlet holes respectively are the same, partially the same or different.

In an embodiment, the shapes and the sizes of the second gas inlet holes respectively are the same, partially the same or different.

In an embodiment, the etching apparatus further includes:

a plasma disposed between the first electrode plate and the substrate to be processed and located corresponding to the substrate to be processed.

In an embodiment, the etching apparatus further includes:

a stop ring arranged at the second edge region and surrounding the placement region; and

a baffle plate surrounding the second electrode plate and abutting an outer periphery of the stop ring, the baffle plate being provided with a baffle plate opening extending therethrough.

In an embodiment, the gas outlet is opened at a bottom of the chamber and is located corresponding to the baffle plate opening.

In an embodiment, the gas outlet is opened at a side of the chamber and adjacent to the baffle plate opening.

In an embodiment, the substrate to be processed comprises a glass substrate and a film covering a surface of the glass substrate, the film being provided with a cut-out region corresponding to a pattern to be etched.

In the etching apparatus according to an embodiment of the present disclosure, since the cross sectional area of the first gas inlet hole opened in the first central region is smaller than the cross sectional area of the second gas inlet hole opened in the first edge region, when process gas enters an etching apparatus through the first gas inlet holes and the second gas inlet holes, the flow rate of the process gas passing through the second gas inlet holes is smaller than the flow rate of the process gas passing through the first gas inlet holes, thereby further reducing the etching rate of the edge region of the substrate such that the etching rate of the edge region of the substrate is closer to the etching rate of the central region of the substrate, thereby effectively improving process uniformity of various portions of the substrate to be processed.

The present disclosure further provides an etching apparatus includes:

a chamber;

a first electrode plate arranged at an upper part in the chamber and having a first central region and a first edge region surrounding the first central region;

a second electrode plate arranged at a lower part in the chamber and opposite to the first electrode plate and having a placement region and a second edge region surrounding the placement region, a substrate to be processed being disposed at the placement region;

first gas inlet holes configured to be connected to a gas intake device, the first gas inlet holes extending through the first central region and facing the substrate to be processed;

second gas inlet holes configured to be connected to the gas intake device, the second gas inlet holes extending through the first edge region and surrounding the plurality of first gas inlet holes, a cross sectional area of the first gas inlet hole being smaller than the cross sectional area of the second gas inlet hole;

a plasma disposed between the first electrode plate and the substrate to be processed and located corresponding to the substrate to be processed;

a stop ring arranged at the second edge region and surrounding the placement region;

a baffle plate surrounding the second electrode plate and abutting an outer periphery of the stop ring, the baffle plate being provided with a baffle plate opening extending therethrough; and

a gas outlet configured to be connected to a gas suction device, the gas outlet being arranged at the lower part in the chamber and the position of the gas outlet being lower than the position of the second electrode plate.

In the etching apparatus according to an embodiment of the present disclosure, since the cross sectional area of the first gas inlet hole opened in the first central region is smaller than the cross sectional area of the second gas inlet hole opened in the first edge region, when process gas enters an etching apparatus through the first gas inlet holes and the second gas inlet holes, the flow rate of the process gas passing through the second gas inlet holes is smaller than the flow rate of the process gas passing through the first gas inlet holes, thereby further reducing the etching rate of the edge region of the substrate such that the etching rate of the edge region of the substrate is closer to the etching rate of the central region of the substrate, thereby effectively improving process uniformity of various portions of the substrate to be processed.

By providing the plasma, the substrate to be processed can be better treated by the process gas, and the etching effect can be effectively improved. The stop ring can stabilize and fix the substrate to be processed. The baffle plate can prevent the slag generated after the rupture of the substrate to be processed from falling directly into the gas outlet to enter the gas suction device, causing damage to the gas suction device, on the other hand it has certain blocking effect on the process gas, thereby controlling the flow rate and the flow direction of the process gas, so that the process gas can enter the gas outlet through the baffle plate opening opened in the baffle plate.

### BRIEF DESCRIPTION OF THE DRAWINGS

In order to more clearly illustrate the technical solutions in the embodiments of the present disclosure, the drawings used in the description of embodiments or the prior art will be briefly described below. Obviously, the drawings in the following description are only for some embodiments the present disclosure, for those skilled in the art, other drawings may be obtained from these drawings, without the need for creative labor.

FIG. 1 is a first schematic structural view of a first electrode plate of an etching apparatus according to an embodiment of the present disclosure;

FIG. 2 is a second schematic structural view of a first electrode plate of an etching apparatus according to an embodiment of the present disclosure;

FIG. 3 is a schematic structural view of an example of an electrode plate;

FIG. 4 is a first schematic cross sectional view of an etching apparatus according to an embodiment of the present disclosure;

FIG. 5 is a second schematic cross sectional view of an etching apparatus according to an embodiment of the present disclosure;

FIG. 6 is a third schematic cross sectional view of an etching apparatus according to an embodiment of the present disclosure; and

FIG. 7 is a schematic plan structural view of an etching apparatus according to an embodiment of the present disclosure.

### DESCRIPTION OF EMBODIMENTS

In order to make the technical problems to be solved by the present disclosure, technical solutions and beneficial effects more clear, the present disclosure will be further described in detail below with reference to the accompanying drawings and embodiments. It should be understood that the specific embodiments described herein are merely illustrative of the present disclosure and are not intended to limit the present disclosure.

It should be noted that when an element is referred to as being “disposed on” another element, it can be directly disposed on another element or indirectly disposed on another element. When an element is referred to as being “connected to” another element, it can be directly connected to another element or indirectly connected to another element. Moreover, the terms “first” and “second” are used for descriptive purposes only and should not to be construed as indicating or implying a relative importance or implicitly indicating the number of technical features indicated. Thus, features with “first” or “second” may include one or more of the features either explicitly or implicitly. In the description of the present disclosure, the term “a plurality of” means two or more, unless otherwise specifically defined.

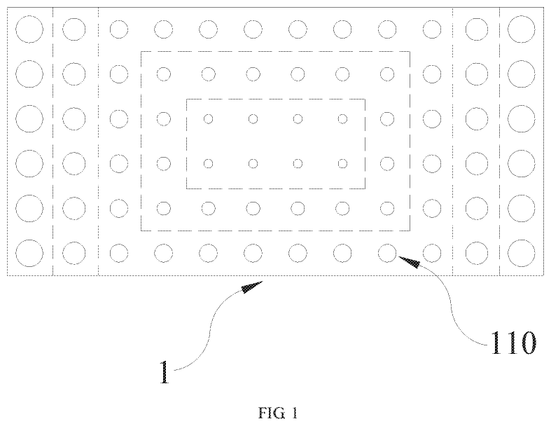

Referring to FIG. 1, an electrode assembly, which may be applied to an etching apparatus, includes a first electrode plate 1. The first electrode plate 1 has a first central region 11 and a first edge region 12 surrounding the first central region 11. First gas inlet holes 111 connected to a gas intake device 7 extend through the first central region 11 and second gas inlet holes 121 connected to the gas intake device 7 extend through the first edge region 11. The second gas inlet holes 121 surround the first gas inlet holes 111. The cross sectional area of the first gas inlet hole 111 is smaller than the cross sectional area of the second gas inlet hole 121.

In the electrode assembly according to an embodiment of the present disclosure, since the cross sectional area of the first gas inlet hole 111 opened in the first central region 11 is smaller than the cross sectional area of the second gas inlet hole 121 opened in the first edge region 12, when the process gas enters an etching apparatus through the first gas inlet holes 111 and the second gas inlet holes 121, the flow rate of the process gas passing through the second gas inlet holes 121 is smaller than the flow rate of the process gas passing through the first gas inlet holes 111, thereby further reducing the etching rate of the portion of the substrate to be processed corresponding to the first edge region 12 such that the etching rate of the portion of the substrate to be processed corresponding to the first central region 11 is closer to the etching rate of the portion of the substrate to be processed corresponding to the first edge region 12, thereby effectively improving process uniformity of various portions of the substrate to be processed.

In one embodiment, the cross sectional area of the gas inlet hole 110 in the central region of the first electrode plate 1 is the smallest and the cross sectional area of the gas inlet hole 110 in the edge region of the first electrode plate 1 is the largest, the cross sectional areas of all gas inlet holes 110 located in the first electrode plate 1 may be configured in an arithmetic progression such that the cross sectional areas of all gas inlet holes 110 in the first electrode plate 1 increase from the central region of the first electrode plate 1 to the edge region of the first electrode plate 1.

It should be understood that the cross sectional areas of the gas inlet holes 110 in the first electrode plate 1 may alternatively be configured in other manners, as long as the cross sectional areas of the gas inlet holes 110 increase from the central region of the first electrode plate 1 to the edge region of the first electrode plate 1. The change of the cross sectional areas of the gas inlet holes 110 from the center region of the first electrode plate 1 to the edge region of the first electrode plate 1 may be a linear change, a step change, or any other variation, which is not limited herein, as long as the cross sectional areas of the gas inlet holes 110 increase from the central region of the first electrode plate 1 to the edge region of the first electrode plate 1.

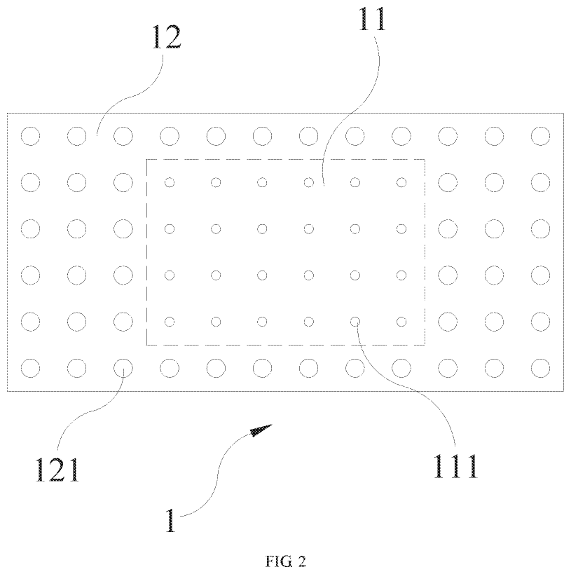

Referring to FIG. 2, in one embodiment, the plurality of first gas inlet holes 111 are uniformly distributed in the first central region 11, so that the flow rate of the process gas flowing through the first central region 11 is the same and the etching rate of the portion of the substrate to be processed corresponding to the first central region 11 is the same, thereby effectively improving the process uniformity of the portion of the substrate to be processed corresponding to the first central region 11. The plurality of second gas inlet holes 121 are uniformly distributed in the first edge region 12, so that the flow rate of the process gas flowing through the first edge region 12 is the same and the etching rate of the portion of the substrate to be processed corresponding to the first edge region 12 is the same, thereby effectively improving the process uniformity of the portion of the substrate to be processed corresponding to the first edge region 12.

In one embodiment, the plurality of first gas inlet holes 111 are distributed in the first central region 11 in a non-uniform or partially uniform manner, and the plurality of second gas inlet holes 121 are distributed in the first edge region 12 in a non-uniform or partially uniform manner such that the etching rate of the portion of the substrate to be processed corresponding to the first central region 11 is the same as the etching rate of the portion of the substrate to be processed corresponding to the first edge region 12.

In one embodiment, the plurality of first gas inlet holes 111 have the same shapes and sizes and the cross sectional areas of the plurality of first gas inlet holes 111 are accordingly the same, so that the flow rate of the process gas flowing through the first central region 11 is the same, therefore the etching rate of the portion of the substrate to be processed corresponding to the first central region 11 is the same, thereby effectively improving the process uniformity of the portion of the substrate to be processed corresponding to the first central region 11.

The plurality of second gas inlet holes 121 have the same shapes and sizes, so that the flow rate of the process gas flowing through the first edge region 12 is the same, therefore the etching rate of the portion of the substrate to be processed corresponding to the first edge regions 12 is the same, thereby effectively improving the process uniformity of the portion of the substrate to be processed corresponding to the first edge region 12.

The cross sectional area of the first gas inlet holes 111 and the cross sectional area of the second gas inlet holes 121 are carefully designed so that the etching rate of the central region of the substrate to be processed (i.e., the etching rate of the portion of the substrate to be processed corresponding to the first central region 11) is the same as the etching rate of the edge region of the substrate to be processed (i.e., the etching rate of the portion of the substrate to be processed corresponding to the first edge region 12), which improves the process uniformity of the respective portions of the substrate to be processed.

In one embodiment, the sizes and shapes of the plurality of first gas inlet holes 111 are partially the same and sizes and shapes of the plurality of second gas inlet holes 121 are partially the same such that the etching rate of the portion of the substrate to be processed corresponding to the first central region 11 is the same as the etching rate of the portion of the substrate to be processed corresponding to the first edge region 12.

In one embodiment, the plurality of first gas inlet holes 111 have different sizes and shapes and the plurality of second gas inlet holes 121 have different sizes and shapes such that the etching rate of the portion of the substrate to be processed corresponding to the first central region 11 is the same as the etching rate of the portion of the substrate to be processed corresponding to the first edge region 12.

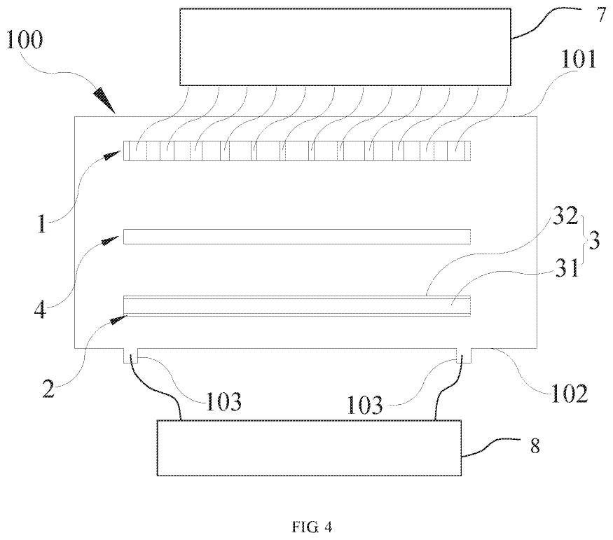

Referring to FIG. 1 and FIG. 4, an embodiment of the present disclosure further provides an etching apparatus including a chamber 100 for etching a substrate 3 to be processed, a first electrode plate 1 and a second electrode plate 2. The electrode plate 1 is arranged at an upper part in the chamber 100, near the top 101 of the chamber 100 and has a first central region 11 and a first edge region 12 surrounding the first central region 11. The first central region 11 is provide with first gas inlet holes 111 extending therethrough. The first gas inlet holes 111 are connected to a gas intake device 7. The first edge region 12 is provided with second gas inlet holes 121 extending therethrough. The second gas inlet holes 121 are connected to the gas intake device 7 and surround the first gas inlet holes 111. The cross sectional area of the first gas inlet hole 111 is smaller than the cross sectional area of the second gas inlet hole 121. The second electrode plate 2 is arranged at a lower part in the chamber 100, near the bottom 102 of the chamber 100 and opposite to the first electrode plate 1. The second electrode plate 2 has a placement region 33 and a second edge region 34 surrounding the placement region. The substrate 3 to be processed is disposed at the placement region and the position of the first electrode plate 1 corresponds to the position of the substrate 3 to be processed. The chamber 100 is also provided with gas outlets 103 configured to be connected to a gas suction device 8. The gas outlets 103 are arranged at the lower part in the chamber and the position of the gas outlets 103 are lower than the position of the second electrode plate 2.

The working principle of an etching apparatus according to an embodiment of the present disclosure is as follows. Firstly, the substrate 3 to be processed is disposed on the second electrode plate 2. Then the gas intake device 7 is connected with the first gas inlet holes 111 and the second gas inlet holes 121, the gas suction device 8 is connected with the gas outlets 103, and the gas suction device 8 and the gas intake device 7 are started so that the process gas enters the chamber 100 through the first gas inlet holes 111 and the second gas inlet holes 121 and etches the substrate 3 to be processed. The process gas is finally discharged to the outside of the chamber 100 through the gas outlets.

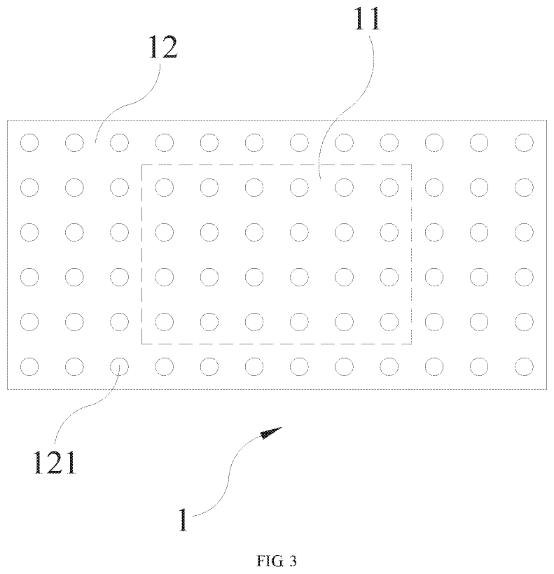

Specifically, referring to FIG. 3, in an example, in the case that the cross sectional areas of the gas inlet holes are not adjusted, since the process gas flows toward the corners inside the chamber 100 and the edge region of the substrate 3 to be processed is more close to the four corners of the chamber 100, the etching rate of the edge region of the substrate is greater than the etching rate of the central region of the substrate, resulting in different etching degrees of the various portions of the substrate 3 to be processed, so that the process uniformity of various portions of the substrate 3 to be processed is bad.

Referring to FIG. 4, in the embodiment, the cross sectional area of the second gas inlet hole 121 is greater than the cross sectional area of the first gas inlet hole 111 so that the pressure of the process gas passing through the second gas inlet holes 121 is smaller than that the pressure of the process gas passing through the first gas inlet hole 121, therefore the flow rate of the process gas flowing through the second gas inlet holes 121 is smaller than the flow rate of the process gas flowing through the first gas inlet holes 111 and the amount of the process gas flowing to the four corners of the chamber 100 is accordingly reduced, thus the etching rate of the edge region of the substrate can be decreased and the etching rate of the edge region of the substrate is closer to the etching rate of the central region of the substrate, thereby improving the process uniformity of portions of the substrate 3 to be processed.

In the etching apparatus according to an embodiment of the present disclosure, since the cross sectional area of the first gas inlet hole 111 opened in the first central region 11 is smaller than the cross sectional area of the second gas inlet hole 121 opened in the first edge region 12, when the process gas enters the chamber 100 through the first gas inlet holes 111 and the second gas inlet holes 121, the flow rate of the process gas passing through the second gas inlet holes 121 is smaller than the flow rate of the process gas passing through the first gas inlet holes 111, thereby reducing the etching rate of the edge region of the substrate such that the etching rate of the edge region of the substrate is closer to the etching rate of the central region of the substrate, thereby effectively improving the process uniformity of various portions of the substrate to be processed.

In one embodiment, the cross sectional area of the gas inlet hole 110 in the central region of the first electrode plate 1 is the smallest and the cross sectional area of the gas inlet hole 110 in the edge region of the first electrode plate 1 is the largest, the cross sectional areas of all gas inlet holes 110 in the first electrode plate 1 may be arranged in an arithmetic progression such that the cross sectional areas of all gas inlet holes 110 in the first electrode plate 1 increase from the central region of the first electrode plate 1 to the edge region of the first electrode plate 1.

It should be understood that the cross sectional areas of the gas inlet holes 110 in the first electrode plate 1 may alternatively be configured in other manners, as long as the cross sectional areas of the gas inlet holes 110 increase from the central region of the first electrode plate 1 to the edge region of the first electrode plate 1. The change of the cross sectional areas of the gas inlet holes 110 from the center region of the first electrode plate 1 to the edge region of the first electrode plate 1 may be a linear change, a step change, or any other variation, which is not limited herein, as long as the cross sectional areas of the gas inlet holes 110 increase from the central region of the first electrode plate 1 to the edge region of the first electrode plate 1.

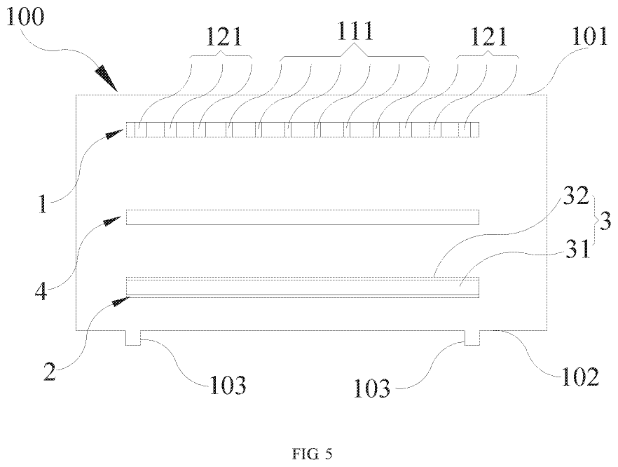

Referring to FIG. 2 and FIG. 5, in one embodiment, the plurality of first gas inlet holes 111 are uniformly distributed in the first central region 11 and the flow rate of the process gas passing through each of the first gas inlet holes 111 is the same, so that the flow rate of the process gas entering the first central region 11 is the same and the etching rate of the central region of the substrate is the same, thereby effectively improving the process uniformity of the central region of the substrate to be processed. The plurality of second gas inlet holes 121 are uniformly distributed in the first edge region 12 and the flow rate of the process gas passing through each of the second gas inlet holes 111 is the same, so that the flow rate of the process gas entering the first edge region 12 is the same and the etching rate of the edge region of the substrate is the same, thereby effectively improving the process uniformity of the edge region of the substrate to be processed.

In one embodiment, the plurality of first gas inlet holes 111 are distributed in the first central region 11 in a non-uniform or partially uniform manner and the plurality of second gas inlet holes 121 are distributed in the first edge region 12 in a non-uniform or partially uniform manner such that the etching rate of the central region of the substrate is the same as the etching rate of the edge region of the substrate.

In one embodiment, the plurality of first gas inlet holes 111 have the same shapes and sizes and the cross-sectional areas of the plurality of first gas inlet holes 111 are accordingly the same such that the flow rate of the process gas flowing through the first central region 11 is the same, therefore the etching rate of the central region of the substrate is the same, thereby effectively improving the process uniformity of the central region of the substrate. The plurality of second gas inlet holes 121 have the same shapes and sizes, such that the flow rate of the process gas flowing through the first edge region 12 is the same, therefore the etching rate of the edge region of the substrate is the same, thereby effectively improving the process uniformity of the edge region of the substrate. The cross sectional area of the first gas inlet hole 111 and the cross sectional area of the second gas inlet hole 121 are carefully designed so that the etching rate of the central region of the substrate is the same as the etching rate of the edge region of the substrate, which improves the process uniformity of the respective portions of the substrate to be processed.

In one embodiment, the sizes and shapes of the plurality of first gas inlet holes 111 are partially the same and sizes and shapes of the plurality of second gas inlet holes 121 are partially the same such that the etching rate of the central region of the substrate is the same as the etching rate of the edge region of the substrate.

In one embodiment, the plurality of first gas inlet holes 111 have different sizes and shapes and the plurality of second gas inlet holes 121 have different sizes and shapes such that the etching rate of the central region of the substrate is the same as the etching rate of the edge region of the substrate.

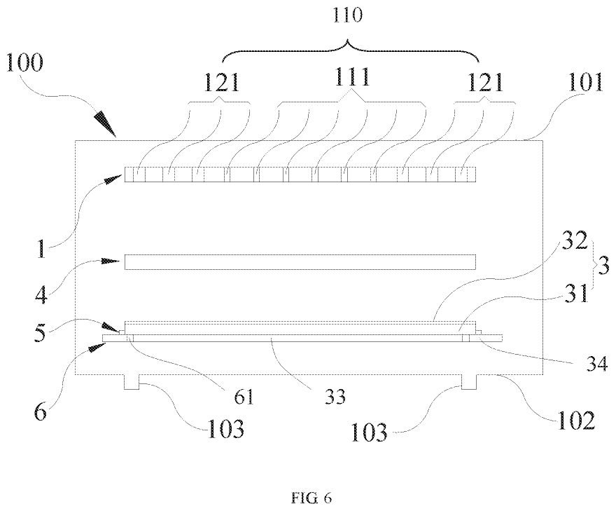

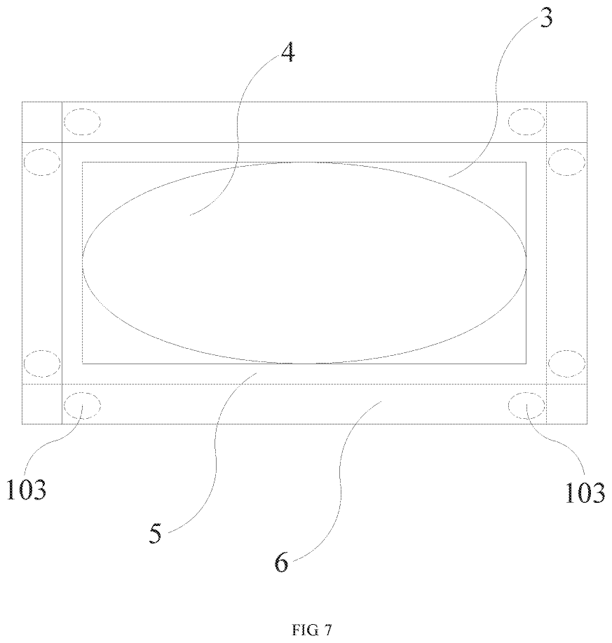

Referring to FIG. 6 and FIG. 7, in one embodiment, the etching apparatus further includes a plasma 4 disposed between the first electrode plate 1 and the substrate 3 to be processed and corresponding to the position of the substrate 3 to be processed. Alternatively, the plasma 4 is located on one side close to the substrate 3 to be processed. In operation, the process gas enters the chamber 100 through the first gas inlet holes 111 and the second gas inlet holes 121 to reach the plasma 4, the plasma 4 decomposes the molecules of the process gas to generate highly active molecules capable of rapidly etching the substrate 3 to be processed. The plasma 4 also ionize these highly active molecules, the ionized high activity molecules reach the substrate 3 to be processed and convert the material to be etched from the solid phase to the gaseous phase, and then the material is removed out from the chamber 100 through the gas outlets 103 under the action of the gas suction device 8.

By providing the plasma, the substrate to be processed can be better treated by the process gas, and the etching effect can be effectively improved. Since the flow rate of the process gas passing through the second gas inlet holes 121 is smaller than the flow rate of the process gas passing through the first gas inlet holes 111, the consumption of the respective portions of the plasma 4 is more uniform, and etching rate of respective portions of the substrate 3 to be processed is also more uniform, thereby improving the process uniformity of the respective portions of the substrate 3 to be processed.

In one embodiment, the etching apparatus further includes a stop ring 5 and a baffle plate 6. The stop ring is arranged at the second edge region 34 of the second electrode plate 2 and surrounding the placement region. The baffle plate 6 surrounds the second electrode plate 2 and is abutting the outer periphery of the stop ring 5. The baffle plate 6 is provided with a baffle plate opening 61 extending therethrough. When the substrate 3 to be processed is placed in the placement region of the second electrode plate 2, the stop ring 5 disposed around the placement region can stabilize and fix the substrate 3 to be processed. The baffle plate 6 surrounding the second electrode plate 2 can prevent the slag generated after the rupture of the substrate 3 to be processed from falling directly into the gas outlets 103 to enter the gas suction device 8, causing damage to the gas suction device 8, on the other hand it has certain blocking effect on the process gas, thereby controlling the flow rate and the flow direction of the process gas, so that the process gas can enter the gas outlets 103 through the baffle plate opening 61 opened in the baffle plate 6.

Optionally, a plurality of through holes are formed in the baffle plate 6 corresponding to the position of the gas outlets 103, so that the flow rate, flow direction, and distribution uniformity of the process gas can be further adjusted, thereby further improving the process uniformity of various portions of the substrate 3 to be processed.

In one embodiment, the substrate 3 to be processed 3 includes a glass substrate 31 and a film 32 covering the surface of the glass substrate 31, and the film 32 is provided with a cut-out area corresponding to the pattern to be etched. The film 32 can protect the glass substrate 31, thereby ensuring that the process gas etches the portion of the glass substrate 31 that needs to be etched while the portion that does not need to be etched cannot contact the process gas due to the covering of the film 32.

In one embodiment, the gas outlets 103 are opened at the bottom 102 of the chamber 100 and the gas outlets 103 correspond to the position of the baffle plate openings 61. Specifically, the bottom 102 is provided with gas outlets 103 at the positions of both ends of each side corresponding to the baffle plate 6, that is, the number of the gas outlets 103 is eight and each of the four corners of the chamber 100 is provided with two gas outlets 103. In this way, on one hand, the process gas can be quickly discharged from the chamber 100 through the gas outlets 103 under the action of the gas suction device 8 after passing through the baffle plate opening 61, and on the other hand the positions of the gas outlets 103 match the positions of the baffle plate opening 61 and also match the first gas inlet holes 111 and the second gas inlet holes 121 opened in the first electrode plate 1, which is benefit to the uniform distribution of the process gas flowing through the substrate 3 to be processed, thus the etching rate of the central region of the substrate is the same as the etching rate of the edge region of the substrate, further improving the process uniformity of the respective portions of the substrate 3 to be processed.

In one embodiment, the gas outlets 103 are opened at one side of the chamber 100, and the positions of the gas outlets 103 are lower than the position of the second electrode plate 2, so that the process gas can enter the gas outlets 103 after passing through the substrate 3 to be processed. The gas outlets 103 are close to the baffle plate openings 61, and on one hand the process gas can be quickly discharged from the chamber 100 through the gas outlets 103 under the action of the gas suction device 8 after passing through the baffle plate openings 61, and on the other hand the positions of the gas outlets 103 match the positions of the baffle plate openings 61 and also match the first gas inlet holes 111 and the second gas inlet holes 121 opened in the first electrode plate 1, which is benefit to the uniform distribution of the process gas flowing through the substrate 3 to be processed, thus the etching rate of the central region of the substrate is the same as the etching rate of the edge region of the substrate, further improving the process uniformity of the respective portions of the substrate 3 to be processed. It should be understood that the number and positions of the gas outlets 103 can be set as desired.

Referring to FIG. 4 to FIG. 7, an embodiment of the present disclosure further provides an etching apparatus including a chamber 100 for etching a substrate 3 to be processed, a first electrode plate 1 and a second electrode plate 2. The electrode plate 1 is arranged at an upper part in the chamber 100, near the top 101 of the chamber 100, and has a first central region 11 and a first edge region 12 surrounding the first central region 11. The first central region 11 is provide with first gas inlet holes 111 extending therethrough. The first gas inlet holes 111 are connected to a gas intake device 7. The first edge region 12 is provided with second gas inlet holes 121 extending therethrough. The second gas inlet holes 121 are connected to the gas intake device 7 and surround the first gas inlet holes 111. The cross sectional area of the first gas inlet hole 111 is smaller than the cross sectional area of the second gas inlet hole 121. The second electrode plate 2 is arranged at a lower part in the chamber 100, near the bottom 102 of the chamber 100, and opposite to the first electrode plate 1. The second electrode plate 2 has a placement region 33 and a second edge region 34 surrounding the placement region. The substrate 3 to be processed is disposed at the placement region and the position of the first electrode plate 1 corresponds to the position of the substrate 3 to be processed. The chamber 100 is also provided with gas outlets 103 configured to be connected to a gas suction device 8. The gas outlets 103 are arranged at the lower part in the chamber and the position of the gas outlets 103 are lower than the position of the second electrode plate 2.

The etching apparatus further includes a plasma 4, a stop ring 5 and a baffle plate 6. The plasma 4 is disposed between the first electrode plate 1 and the substrate 3 to be processed and corresponds to the position of the substrate 3 to be processed. The stop ring 5 is arranged at the second edge region 34 of the second electrode plate 2 and surrounds the placement region. The baffle plate 6 surrounds the second electrode plate 2 and is abutting the outer periphery of the stop ring 5, and the baffle plate 6 is provided with a baffle plate opening 61 extending therethrough.

Alternatively, the plasma 4 is located on one side close to the substrate 3 to be processed. In operation, the process gas enters the chamber 100 through the first gas inlet holes 111 and the second gas inlet holes 121 to reach the plasma 4, the plasma 4 decomposes the molecules of the process gas to generate highly active molecules capable of rapidly etching the substrate 3 to be processed. The plasma 4 also ionize these highly active molecules, the ionized high activity molecules reach the substrate 3 to be processed and convert the material to be etched from the solid phase to the gaseous phase, and then the material is removed out from the chamber 100 through the gas outlets 103 under the action of the gas suction device 8.

In the etching apparatus according to an embodiment of the present disclosure, since the cross sectional area of the first gas inlet holes 111 opened in the first central region 11 is smaller than the cross sectional area of the second gas inlet holes 121 opened in the first edge region 12, when the process gas enters the chamber 100 through the first gas inlet holes 111 and the second gas inlet holes 121, the flow rate of the process gas passing through the second gas inlet holes 121 is smaller than the flow rate of the process gas passing through the first gas inlet holes 111, thereby further reducing the etching rate of the edge region of the substrate such that the etching rate of the edge region of the substrate is closer to the etching rate of the central region of the substrate, thereby effectively improving process uniformity of various portions of the substrate to be processed.

By providing the plasma, the substrate to be processed can be better treated by the process gas, and the etching effect can be effectively improved. Since the flow rate of the process gas passing through the second gas inlet holes 121 is smaller than the flow rate of the process gas passing through the first gas inlet holes 111, the consumption of the respective portions of the plasma 4 is more uniform, and etching rate of respective portions of the substrate 3 to be processed is also more uniform, thereby improving the process uniformity of the respective portions of the substrate 3 to be processed.

The stop ring 5 can stabilize and fix the substrate 3 to be processed. The baffle plate 6 can prevent the slag generated after the rupture of the substrate 3 to be processed from falling directly into the gas outlets 103 to enter the gas suction device 8, causing damage to the gas suction device 8, on the other hand it has a certain blocking effect on the process gas, thereby controlling the flow rate and the flow direction of the process gas, so that the process gas can enter the gas outlets 103 through the baffle plate opening 61 opened in the baffle plate 6.

The above description is only the preferred embodiment of the present disclosure, and is not intended to limit the present disclosure. Any modifications, equivalent substitutions and improvements made within the spirit and principles of the present disclosure are included in the protection scope of the present disclosure.

1. An electrode assembly, comprising:
a first electrode plate having a first central region and a first edge region surrounding the first central region;
first gas inlet holes configured to be connected to a gas intake device, the first gas inlet holes extending through the first central region; and
second gas inlet holes configured to be connected to the gas intake device, the second gas inlet holes extending through the first edge region and surrounding the first gas inlet holes, and a cross sectional area of the first gas inlet hole being smaller than a cross sectional area of the second gas inlet hole.

2. The electrode assembly according to claim 1, wherein the first gas inlet holes extend through and arrange in the first central region in a uniform or partially uniform manner.

3. The electrode assembly according to claim 1, wherein the first gas inlet holes extend through and arrange in the first central region in a non-uniform manner.

4. The electrode assembly according to claim 1, wherein the second gas inlet holes extend through and arrange in the first edge region in a uniform or partially uniform manner.

5. The electrode assembly according to claim 1, wherein the second gas inlet holes extend through and arrange in the first edge region in a non-uniform manner.

6. The electrode assembly according to claim 1, wherein the shapes and the sizes of the first gas inlet holes respectively are the same, partially the same or different.

7. The electrode assembly according to claim 1, wherein the shapes and the sizes of the second gas inlet holes respectively are the same, partially the same or different.

8. An etching apparatus, comprising:
a chamber;
a first electrode plate arranged at an upper part in the chamber and having a first central region and a first edge region surrounding the first central region;
a second electrode plate arranged at a lower part in the chamber and opposite to the first electrode plate and having a placement region and a second edge region surrounding the placement region, wherein a substrate to be processed being disposed at the placement region;
first gas inlet holes configured to be connected to a gas intake device, the first gas inlet holes extending through the first central region and directly facing the substrate to be processed;
second gas inlet holes configured to be connected to the gas intake device, the second gas inlet holes extending through the first edge region and surrounding the first gas inlet holes, and a cross sectional area of the first gas inlet hole being smaller than the cross sectional area of the second gas inlet hole; and
a gas outlet configured to be connected to a gas suction device, the gas outlet being arranged at the lower part in the chamber and the position of the gas outlet being lower than the position of the second electrode plate.

9. The etching apparatus according to claim 8, wherein the first gas inlet holes extend through and arranged in the first central region in a uniform or partially uniform manner.

10. The etching apparatus according to claim 8, wherein the first gas inlet holes extend through and arrange in the first central region in a non-uniform manner.

11. The etching apparatus according to claim 8, wherein the second gas inlet holes extend through and arrange in the first edge region in a uniform or partially uniform manner.

12. The etching apparatus according to claim 8, wherein the second gas inlet holes extend through and arrange in the first edge region in a non-uniform manner.

13. The etching apparatus according to claim 8, wherein the shapes and the sizes of the first gas inlet holes respectively are the same, partially the same or different.

14. The etching apparatus according to claim 8, wherein the shapes and the sizes of the second gas inlet holes respectively are the same, partially the same or different.

15. The etching apparatus according to claim 8, wherein the etching apparatus further comprises:
a plasma disposed between the first electrode plate and the substrate to be processed and located corresponding to the substrate to be processed.

16. The etching apparatus according to claim 8, wherein the etching apparatus further comprises:
a stop ring arranged at the second edge region and surrounding the placement region; and
a baffle plate surrounding the second electrode plate and abutting an outer periphery of the stop ring, the baffle plate being provided with a baffle plate opening extending therethrough.

17. The etching apparatus according to claim 16, wherein the gas outlet is opened at a bottom of the chamber and is located corresponding to the baffle plate opening.

18. The etching apparatus according to claim 16, wherein the gas outlet is opened at a side of the chamber and adjacent to the baffle plate opening.

19. The etching apparatus according to claim 8, wherein the substrate to be processed comprises a glass substrate and a film covering a surface of the glass substrate, the film being provided with a cut-out region corresponding to a pattern to be etched.

20. An etching apparatus, comprising:
a chamber;
a first electrode plate arranged at an upper part in the chamber and having a first central region and a first edge region surrounding the first central region;
a second electrode plate arranged at a lower part in the chamber and opposite to the first electrode plate and having a placement region and a second edge region surrounding the placement region, wherein a substrate to be processed being disposed at the placement region;
first gas inlet holes configured to be connected to a gas intake device, the first gas inlet holes extending through the first central region and facing the substrate to be processed;
second gas inlet holes configured to be connected to the gas intake device, the second gas inlet holes extending through the first edge region and surrounding the plurality of first gas inlet holes, and a cross sectional area of the first gas inlet hole being smaller than the cross sectional area of the second gas inlet hole;
a plasma disposed between the first electrode plate and the substrate to be processed and located corresponding to the substrate to be processed;
a stop ring arranged at the second edge region and surrounding the placement region;
a baffle plate surrounding the second electrode plate and abutting an outer periphery of the stop ring, the baffle plate being provided with a baffle plate opening extending therethrough; and
a gas outlet configured to be connected to a gas suction device, the gas outlet being arranged at the lower part in the chamber and the position of the gas outlet being lower than the position of the second electrode plate.
